(19) United States
(12) Patent Application Publication
(10) Pub. No.: US 2026/0324151 A1
(43) Pub. Date: Oct. 15, 2026

(54) LIGHT-EMITTING DEVICE, MANUFACTURING METHOD OF LIGHT-EMITTING DEVICE AND VEHICLE LAMP

(71) Applicant: STANLEY ELECTRIC CO., LTD., Tokyo (JP)

(72) Inventors: Kaori TACHIBANA, Tokyo (JP); Hiroaki OKUMA, Tokyo (JP); Yuji SHIGEEDA, Tokyo (JP)

(73) Assignee: STANLEY ELECTRIC CO., LTD., Tokyo (JP)

(21) Appl. No.: 19/646,706

(22) Filed: Apr. 14, 2026

(30) Foreign Application Priority Data
Apr. 15, 2025 (JP) 2025-066661

(51) Int. Cl. H10H 20/855; F21S 41/148; F21S 43/14; H10H 20/01; H10H 20/85; H10H 20/851; H10H 20/854; H10H 20/856

(52) U.S. Cl. CPC H10H 20/855; F21S 41/148; F21S 43/14; H10H 20/021; H10H 20/0361; H10H 20/0362; H10H 20/0363; H10H 20/8506; H10H 20/8514; H10H 20/854; H10H 20/856

(57) ABSTRACT

A light-emitting device includes a substrate, a light-emitting element provided on the substrate, a wavelength conversion member provided on the light-emitting element, a light-reflecting or light-blocking resin molded body provided on the substrate to cover peripheries of the light-emitting element and the wavelength conversion member, a transparent member provided on the wavelength conversion member with an air layer interposed between the wavelength conversion member and the transparent member, and a lens body provided on the resin molded body to cover the transparent member, wherein the air layer is formed by a concave portion formed by recessing a portion of the resin molded body, and the transparent member is provided on the resin molded body to close the concave portion.

### CROSS-REFERENCE TO RELATED APPLICATION

This application is based upon and claims the benefit of priority from Japanese Patent Application No. 2025-066661, filed Apr. 15, 2025, the entire content of which is incorporated herein by reference.

### BACKGROUND OF THE INVENTION

### Field of the Invention

The present invention relates to a light-emitting device, a manufacturing method of the light-emitting device and a vehicle lamp.

### Description of Related Art

For example, light-emitting devices that use a light-emitting element such as a light-emitting diode (LED) as a light source are known (for example, refer to PCT International Publication No. WO2024/128324).

PCT International Publication WO2024/128324 discloses a light-emitting device having an optical function unit including a light-emitting element, a wavelength conversion member disposed on the light-emitting element, a light-reflecting member covering side surfaces of the light-emitting element and side surfaces of the wavelength conversion member, and a lens disposed on the wavelength conversion member.

### SUMMARY OF THE INVENTION

In the light-emitting device described in PCT International Publication WO2024/128324, the optical function unit is provided to be bonded to an upper surface of a light-reflecting member made of resin. For example, after applying uncured resin that becomes a light-reflecting member and curing it, the surface may have dents, distortions, or the like due to so-called resin sink marks.

In this case, if the optical function unit is bonded to a surface of the light-reflecting member, for example, the optical function unit may end up in a different posture than an originally intended posture. Moreover, if dents or distortions occur on the surface of the light-reflecting member, the optical function unit may shift from an optical axis or rotate in a two or three-dimensional direction. As a result, the optical function may not be properly performed and a desired light distribution from the light-emitting device may not be achieved, leading to a reduction in output of light.

Therefore, high positional accuracy of members that constitute the light-emitting device is required to achieve the desired light distribution. However, with a manufacturing method of a conventional light-emitting device, it is difficult to achieve high positional accuracy due to tolerances that arise during each process.

Aspects of the present invention provide a light-emitting device and the manufacturing method of such light-emitting device that make it possible to achieve a desired light distribution with high positional accuracy and improve light extraction efficiency, as well as a vehicle lamp equipped with such a light-emitting device.

Aspects of the present invention provide the following configuration.

[1] A light-emitting device includes a substrate, a light-emitting element provided on the substrate, a wavelength conversion member provided on the light-emitting element, a light-reflecting or light-blocking resin molded body provided on the substrate to cover peripheries of the light-emitting element and the wavelength conversion member, a transparent member provided on the wavelength conversion member with an air layer interposed between the wavelength conversion member and the transparent member, and a lens body provided on the resin molded body to cover the transparent member, wherein the air layer is formed by a concave portion formed by recessing a portion of the resin molded body, and the transparent member is provided on the resin molded body to close the concave portion.

[2] A light-emitting device includes a substrate, a light-emitting element provided on the substrate, a wavelength conversion member provided on the light-emitting element, a light-reflecting or light-blocking resin molded body provided on the substrate to cover peripheries of the light-emitting element and the wavelength conversion member, a transparent member provided on the wavelength conversion member with an air layer interposed therebetween, and a lens body provided on the resin molded body to cover the transparent member, wherein the air layer is formed by a concave portion formed by recessing a portion of the transparent member, and the transparent member is provided on the resin molded body to close the concave portion.

[3] In the light-emitting device according to the aspect of [1], the transparent member may be provided to be fitted into an inside of a stepped portion formed by recessing a periphery of the concave portion of the resin molded body.

[4] In the light-emitting device according to the aspect of [1] or [2], the resin molded body may be provided to cover a periphery of the lens body.

[5] A vehicle lamp includes the light-emitting device according to the aspect of [1] or [2].

[6] A manufacturing method of a light-emitting device includes providing a light-emitting element on a substrate, providing a wavelength conversion member on the light-emitting element, molding a light-reflecting or light-blocking resin molded body on the substrate to cover peripheries of the light-emitting element and the wavelength conversion member, providing a transparent member on the wavelength conversion member with an air layer interposed between the wavelength conversion member and the transparent member, and providing a lens body on the resin molded body to cover the transparent member, wherein the air layer is formed by a concave portion formed by recessing a portion of the resin molded body, and the lens body is molded with the transparent member disposed on the resin molded body to close the concave portion.

[7] A manufacturing method of a light-emitting device includes providing a light-emitting element on a substrate, providing a wavelength conversion member on the light-emitting element, molding a light-reflecting or light-blocking resin molded body on the substrate to cover peripheries of the light-emitting element and the wavelength conversion member, providing a transparent member on the wavelength conversion member with an air layer interposed between the wavelength conversion member and the transparent member, and providing a lens body on the resin molded body to cover the transparent member, wherein the air layer is formed by a concave portion formed by recessing a portion of the transparent member, and the lens body is molded with the transparent member disposed on the resin molded body to close the concave portion.

[8] In the manufacturing method of a light-emitting device according to the aspect of [6], the lens body may be molded while the transparent member is fitted into an inside of a stepped portion formed by recessing a periphery of the concave portion of the resin molded body.

[9] In the manufacturing method of a light-emitting device according to the aspect of [6] or [7], a resin molded body covering a periphery of the lens body may be formed by potting after the lens body is molded.

According to the aspects of the present invention, there are provided a light-emitting device and a manufacturing method thereof that can obtain a desired light distribution with high positional accuracy and improve light extraction efficiency, as well as a vehicle lamp equipped with such a light-emitting device.

### BRIEF DESCRIPTION OF THE DRAWINGS

FIG. 1 is a cross-sectional view which shows a configuration of a light-emitting device according to a first embodiment of the present invention.

FIG. 2 is a cross-sectional view for describing a manufacturing process of the light-emitting device shown in FIG. 1.

FIG. 3 is a cross-sectional view for describing the manufacturing process of the light-emitting device shown in FIG. 1.

FIG. 4 is a cross-sectional view for describing the manufacturing process of the light-emitting device shown in FIG. 1.

FIG. 5 is a cross-sectional view for describing the manufacturing process of the light-emitting device shown in FIG. 1.

FIG. 6 is a cross-sectional view for describing the manufacturing process of the light-emitting device shown in FIG. 1.

FIG. 7 is a plan view for describing the manufacturing process of the light-emitting device shown in FIG. 1.

FIG. 8 is a cross-sectional view which shows a configuration of a light-emitting device according to a second embodiment of the present invention.

FIG. 9 is a cross-sectional view which shows a configuration of a light-emitting device according to a third embodiment of the present invention.

FIG. 10 is a cross-sectional view which shows a configuration of a light-emitting device according to a fourth embodiment of the present invention.

FIG. 11 is a cross-sectional view which shows a configuration of a light-emitting device according to a fifth embodiment of the present invention.

FIG. 12 is a cross-sectional view which shows an example of a vehicle lamp related to a sixth embodiment of the present invention.

### DETAILED DESCRIPTION OF THE INVENTION

Hereinafter, embodiments of the present invention will be described in detail with reference to the drawings.

In the drawings used in the following description, dimensions of respective components may be shown at different scales to make them easier to see, and dimensional proportions of the components may not necessarily be the same as those in reality.

Hereinafter, embodiments of the present invention will be described in detail with reference to the drawings.

In the drawings used in the following description, dimensions of various components may be shown at different scales to make them easier to see, and dimensional proportions of the components may not necessarily be the same as those of actual components. Moreover, materials exemplified in the following description are merely examples, and the present invention is not necessarily limited to these. Appropriate modifications may be made within a range not departing from the scope of the present invention.

In the drawings shown below, an XYZ orthogonal coordinate system is set up, with an X-axis direction representing a first direction X in a horizontal plane of the light-emitting device, a Y-axis direction representing a second direction Y orthogonal to the first direction X in the horizontal plane of the light-emitting device, and a Z-axis direction representing a thickness direction (height direction) Z of the light-emitting device.

### First Embodiment

### Light-Emitting Device

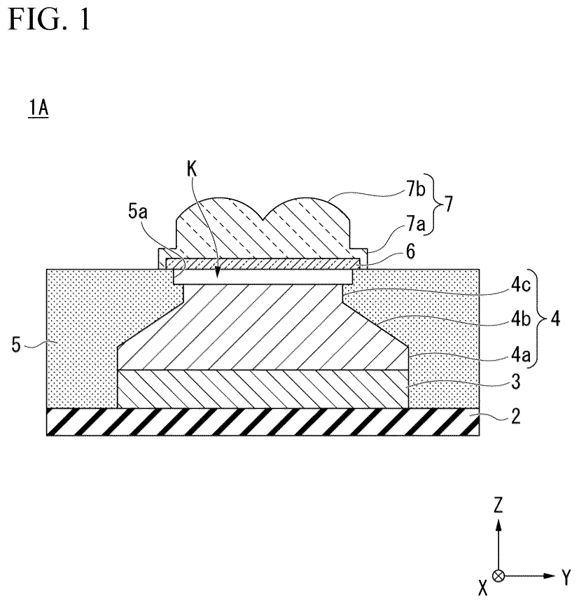

First, as a first embodiment of the present invention, for example, a light-emitting device 1A shown in FIG. 1 will be described.

FIG. 1 is a cross-sectional view which shows a configuration of the light-emitting device 1A.

As shown in FIG. 1, the light-emitting device 1A of the present embodiment includes a substrate 2, a light-emitting element 3 provided on the substrate 2, a wavelength conversion member 4 provided on the light-emitting element 3, a resin molded body 5 provided on the substrate 2 to cover peripheries of the light-emitting element 3 and the wavelength conversion member 4, a transparent member 6 provided on the wavelength conversion member 4 with an air layer K interposed therebetween, and a lens body 7 provided on the resin molded body 5 to cover the transparent member 6.

The substrate 2 is made of, for example, a rectangular flat plate-shaped substrate. The substrate 2 may be made of, for example, a ceramic such as aluminum nitride (AlN) or aluminum oxide (Al₂O₃), or a metal core substrate. Furthermore, the substrate 2 is not limited to the substrate described above, and may be, for example, a case body having a bottom wall and side walls rising from a periphery of the bottom wall, with a concave portion formed on the inside.

The light-emitting element 3 is made of an LED element that emits blue light (excitation light) with a peak wavelength of, for example, 450 nm. The light-emitting element 3 has a rectangular shape in a plan view and is disposed in a center of one surface (an upper surface in the present embodiment) of the substrate 2.

In the present embodiment, the light-emitting element 3 includes a translucent growth substrate, a semiconductor structure layer formed on a bottom surface of the growth substrate, and a pair of element electrodes electrically connected to the semiconductor structure layer, and is flip-chip mounted on the substrate 2. That is, each of a pair of element electrodes is electrically connected to each of a pair of wiring electrodes provided on a surface of the substrate 2. The light-emitting element 3 emits blue light upward using power supplied from an external power source via the pair of wiring electrodes.

The light-emitting element 3 may be mounted on the substrate 2 via wire bonding. In this case, electrode pads formed on a upper surface of the light-emitting element 3 and a wiring whose pattern is formed on the substrate 2 are electrically connected via wires.

The wavelength conversion member 4 is made of a fluorescent body that is excited by the blue light emitted by the light-emitting element 3 and emits yellow light (fluorescent light). The fluorescent body may be, for example, a transparent ceramic fluorescent body plate made of an yttrium aluminum garnet (YAG:Ce) fluorescent body using cerium (Ce) as an activator.

The fluorescent light emitted by the fluorescent body excited by blue light has a broad green to orange wavelength range, for example, between 480 and 700 nm, and a yellow peak wavelength between 520 and 570 nm.

A translucent coating layer may also be provided on an upper surface of the fluorescent body. The coating layer is made of a material, such as a fluorocarbon, that has low affinity with an uncured resin material that will become the resin molded body 5 after curing. The coating layer may also be an optical multilayer film or a glass film. A film thickness of the coating layer can be set to a desired film thickness corresponding to each material and a purpose of use.

For example, when the coating layer is made of a material, such as a fluorocarbon, that has a higher surface free energy than the resin molded body 5, the resin molded body 5 (described below) can be prevented from adhering to the upper surface of the fluorescent body. For example, polytetrafluoroethylene (PTFE) is used as the fluorocarbon resin at this time.

The wavelength conversion member 4 has a rectangular shape corresponding to the upper surface of the light-emitting element 3 in a plan view and is bonded to the upper surface of the light-emitting element 3 via a transparent adhesive. When the light-emitting element 3 is mounted on the substrate 2 via the wire bonding described above, a lower surface of the wavelength conversion member 4 is disposed in a light-emitting region of the upper surface of the light-emitting element 3 from which blue light is emitted. In other words, the wavelength conversion member 4 is disposed in an area of the upper surface of the light-emitting element 3 other than the wire bonding position.

In the present embodiment, the wavelength conversion member 4 has a quadrangular prism-shaped lower portion 4a that rises vertically from the upper surface of the light-emitting element 3, a truncated quadrangular pyramid-shaped middle portion 4b that has an inclined surface that inclines inward from above the lower portion 4a, and a quadrangular prism-shaped upper portion 4c that rises vertically from above the middle portion 4b. In addition, the middle portion 4b of the wavelength conversion member 4 may also have a shape having a curved inclined surface with a predetermined curvature.

Note that the wavelength conversion member 4 is not limited to a shape that becomes smaller upward, such as the lower portion 4a, the middle portion 4b, and the upper portion 4c described above, and may be a shape that has a constant shape upward, such as a cube or rectangular parallelepiped.

In the light-emitting device 1A of the present embodiment, it is possible to generate white light by mixing the blue light (excitation light) emitted by the light-emitting element 3 described above with the yellow light (fluorescent light) emitted by the wavelength conversion member 4 excited by this blue light.

Therefore, in the light-emitting device 1A of the present embodiment, the light-emitting element 3 and the wavelength conversion member 4 function as a light-emitting unit that emits white light toward the lens body 7. In addition, it is assumed that an optical axis of the white light emitted from this light-emitting unit coincides with a third direction Z, which passes through centers of the light-emitting element 3 and the wavelength conversion member 4. Furthermore, the white light emitted from the light-emitting unit has a Lambertian light distribution.

The resin molded body 5 is made by molding a molding resin containing a light-reflecting or light-blocking filler. In the present embodiment, the resin molded body 5 is made of a light-reflecting member. For example, a silicone resin (refractive index n=1.41) containing TiO₂ particles or SiO₂ particles is used as the light-reflecting member. Note that in the present embodiment, a concentration of the light-reflecting member contained in the resin molded body 5 is, for example, in a range of 15 to 60 mass %, but the present invention is not necessarily limited to this concentration.

In addition to the TiO₂ particles described above, for example, metal oxide particles such as aluminum oxide (Al₂O₃) can also be used as the filler. For the molding resin, in addition to the silicone resin described above, a thermosetting resin can also be used.

The resin molded body 5 is provided on the substrate 2 to cover an entire periphery of side surfaces of the light-emitting element 3 and the wavelength conversion member 4, except for an upper surface of the wavelength conversion member 4. In other words, the light-emitting element 3 and the wavelength conversion member 4 are provided to be embedded in the resin molded body 5, so that the upper surface of the wavelength conversion member 4 is exposed from an upper surface of the resin molded body 5 molded on the substrate 2.

The air layer K is formed by a concave portion 5a formed by recessing a portion of the resin molded body 5. The concave portion 5a is formed by recessing a portion of the upper surface of the resin molded body 5 into a rectangular shape in plan view, which is larger than the upper surface of the wavelength conversion member 4, so that the upper surface of the wavelength conversion member 4 is exposed. As a result, a bottom surface of the concave portion 5a is formed flush with the upper surface of the wavelength conversion member 4.

The resin molded body 5, serving as a light-reflecting member, reflects or scatters light reaching the side surfaces of the light-emitting element 3 and the wavelength conversion member 4 among the blue light emitted by the light-emitting element 3 and the yellow light emitted by the wavelength conversion member 4. As a result, the light-emitting device 1A of the present embodiment prevents light from leaking to the outside from the side surfaces of the light-emitting element 3 and the wavelength conversion member 4. The concave portion 5a in the resin molded body 5 increases a proportion of light that travels toward the lens body 7. That is, light extraction efficiency is improved.

Instead of the light-reflecting member described above, the resin molded body 5 may be made of a light-blocking member that blocks the blue light emitted by the light-emitting element 3 and the yellow light emitted by the wavelength conversion member 4. For example, a silicone resin containing carbon particles may be used as the light-blocking member. In this case, it is also possible to prevent light from leaking to the outside from the side surfaces of the light-emitting element 3 and the wavelength conversion member 4.

The transparent member 6 is made of a rectangular flat plate-shaped transparent substrate and is disposed on the resin molded body 5 to close the concave portion 5a described above. The transparent member 6 is made of transparent substrates such as glass, sapphire, or quartz. Transparent resin substrates such as acrylic resin, polycarbonate (PC) resin, or polyethylene terephthalate (PET) resin are also used. A thickness of the transparent member 6 is preferably 10 to 100 μm, and more preferably 50 μm or less.

The concave portion 5a, closed by the transparent member 6, forms an air layer K between the wavelength conversion member 4, the resin molded body 5, and the transparent member 6.

The lens body 7 is molded onto the resin molded body 5 described above using a light-transmitting molding resin such as a thermosetting resin. The lens body 7 has a rectangular flat plate-shaped base portion 7a that is positioned on the upper surface of the resin molded body 5 and covers upper surfaces and side surfaces of the transparent member 6, and at least one or more (four of 2×2 in the present embodiment) lens portions 7b that protrude spherically from the upper surface of the base portion 7a.

Furthermore, a width of the lens portion 7b of the lens body 7 is preferably shorter than a width of the air layer K. As a result, it is easier to achieve the desired light distribution through the lens portions 7b. Moreover, a refractive index of the lens body 7 is preferably smaller than that of the transparent member 6.

In addition, the plurality of lens portions 7b are disposed radially with respect to a center of the base portion 7a, and have a shape in which adjacent lens portions 7b are connected to each other in the first direction X and the second direction Y. The center of the base portion 7a coincides with a center of a light-emitting portion (the light-emitting element 3 and the wavelength conversion member 4) in the third direction Z.

The lens body 7 is not limited to a configuration having four lens portions 7b (2×2) described above, and it may have, for example, a configuration in which a fifth lens portion 7b is added to a center of the four lens portions 7b described above, or a configuration in which nine lens portions 7b (3×3) are disposed. It may also have a configuration in which one lens portion 7b is disposed in the center of the base portion 7a.

By changing the number, disposition, shape, and the like of the lens portions 7b in the lens body 7, it is possible to control light distribution of light emitted through these lens portions 7b.

In the light-emitting device 1A of the present embodiment, having a configuration as described above, white light is generated by mixing the blue light (excitation light) emitted by the light-emitting element 3 and the yellow light (fluorescent light) emitted by the wavelength conversion member 4 excited by the blue light. The generated white light is incident on the base portion 7a of the lens body 7 through the air layer K, and is then emitted to the outside of the lens body 7 while being refracted on a surface of the lens portion 7b.

Here, the white light emitted from the upper surface of the wavelength conversion member 4 is emitted toward the air layer K, which has a lower refractive index than the wavelength conversion member 4, and is then incident on the base portion 7a of the lens body 7, which has a higher refractive index than the air layer K. In this case, according to Snell's law, the white light incident on the base portion 7a is narrowed in angle and incident on the lens portion 7b while being refracted toward the optical axis.

Therefore, in the light-emitting device 1A of the present embodiment, by providing the air layer K between the wavelength conversion member 4 and the lens body 7, it is possible to increase a narrow-angle component of light emitted to the outside from the lens body 7.

Note that, in the present embodiment, the narrow-angle component of light refers to a component of light emitted within an angular range of 30° with respect to the optical axis (0°) in the Z-axis direction.

In the light-emitting device 1A of the present embodiment, the lens body 7 is provided on the resin molded body 5 by molding. Moreover, the concave portion 5a closed by the transparent member 6 forms the air layer K among the wavelength conversion member 4, the resin molded body 5, and the transparent member 6.

As a result, in the light-emitting device 1A of the present embodiment, the lens body 7 can be attached to the resin molded body 5 by molding with high accuracy while the molding resin forming the lens body 7 is prevented from seeping into an inside of the concave portion 5a.

Therefore, in the light-emitting device 1A of the present embodiment, the high positional accuracy of the lens body 7 described above makes it possible to achieve a desired light distribution and to improve light extraction efficiency.

### Manufacturing Method of Light-Emitting Device

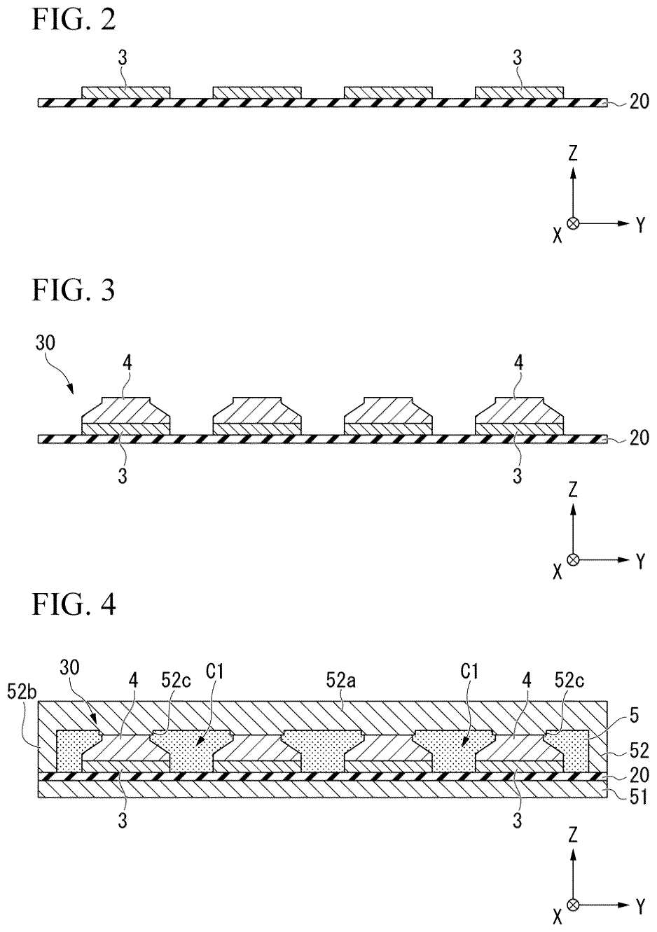

Next, a manufacturing method of the light-emitting device 1A described above will be described with reference to FIGS. 2 to 7.

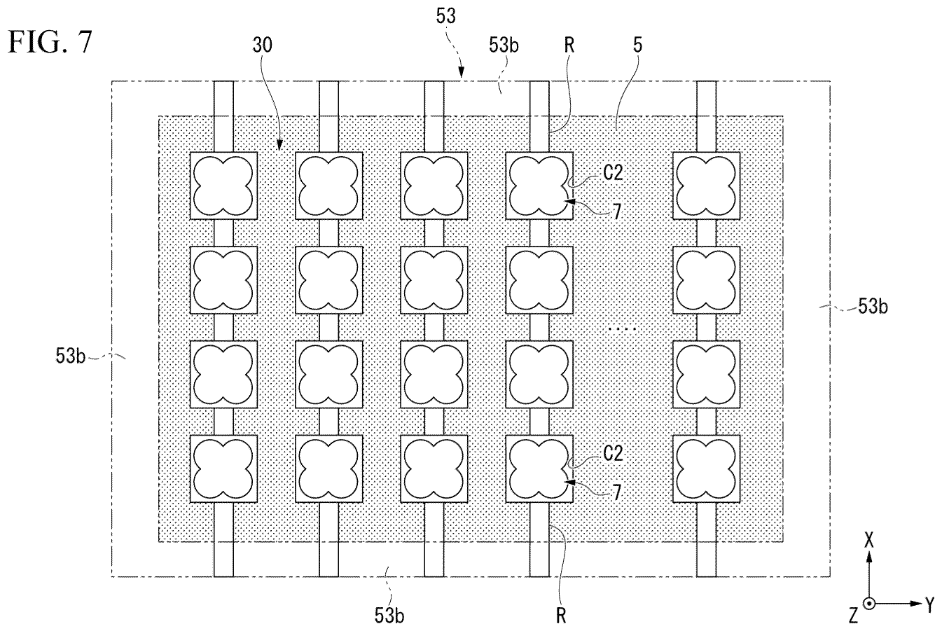

Note that FIGS. 2 to 6 are cross-sectional views for sequentially describing a manufacturing process of the light-emitting device 1A. FIG. 7 is a plan view for describing the manufacturing process of the light-emitting device 1A shown in FIG. 6.

When the light-emitting device 1A is manufactured, first, as shown in FIG. 2, a rectangular flat plate-shaped mother substrate 20, which will serve as the substrate 2, is prepared. Then, a plurality of light-emitting elements 3 are mounted on this mother substrate 20, aligned at predetermined intervals in the first direction X and the second direction Y.

Next, as shown in FIG. 3, an intermediate body 30 is produced by bonding the wavelength conversion member 4 to each surface of the plurality of light-emitting elements 3 via a transparent adhesive.

Next, as shown in FIG. 4, the intermediate body 30 is installed to be interposed between a pair of upper and lower molds 51 and 52.

Among a pair of molds 51 and 52, the lower mold 51 has a flat plate shape corresponding to the mother substrate 20 and mounts an intermediate body 30 thereon. On the other hand, the upper mold 52 has an upper wall 52a facing the mother substrate 20 and a side wall 52b abutting against a periphery of the mother substrate 20, and forms a cavity space C1 for molding the resin molded body 5 between the upper mold 52 and the mother substrate 20.

The upper mold 52 also has a plurality of convex portions 52c forming the concave portion 5a and provided to protrude from a lower surface of the upper wall 52a. Each convex portion 52c abuts against an upper surface of each piece of the wavelength conversion member 4.

From this state, the cavity space C1 is filled with uncured molding resin that forms the resin molded body 5 described above. Then, after this molding resin is heated and cured, the upper mold 52 is released to mold the resin molded body 5 having the concave portion 5a formed on the upper surface of each piece of the wavelength conversion member 4.

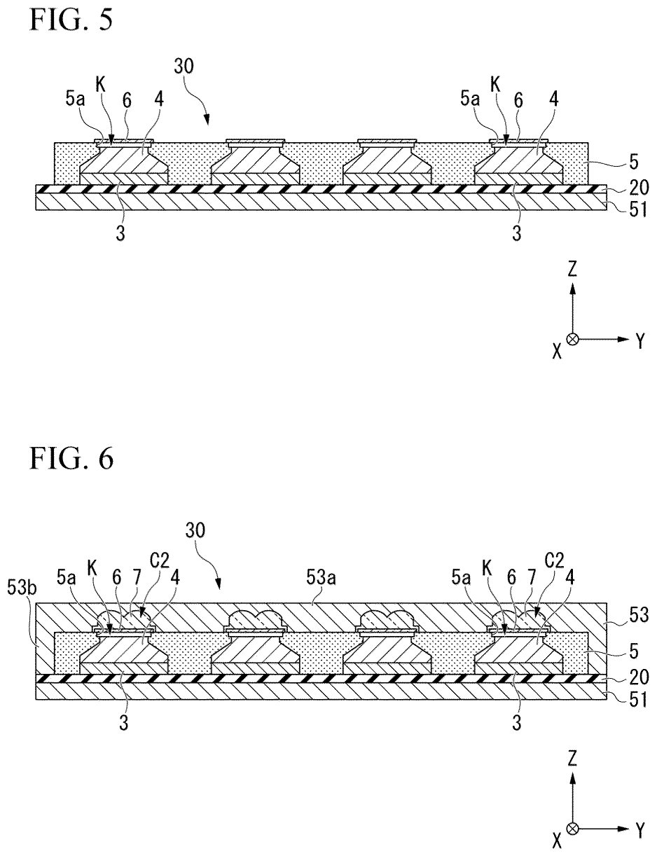

Next, as shown in FIG. 5, the transparent member 6 is disposed on the resin molded body 5 to close each concave portion 5a. At this time, the transparent member 6 is attached to the resin molded body 5 using a transparent adhesive. Alternatively, the transparent member 6 is pressed against the resin molded body 5 in a pressure-bonded (or adhesive) state. As a result, the concave portions 5a closed by the transparent member 6 form the air layer K between the wavelength conversion member 4, the resin molded body 5, and the transparent member 6.

Next, as shown in FIGS. 6 and 7, the intermediate body 30 is installed to be interposed between a pair of upper and lower molds 51 and 53. The upper mold 53 has an upper wall 53a facing the mother substrate 20 and a side wall 53b abutting against the periphery of the mother substrate 20. Between the upper mold 53 and the mother substrate 20, a cavity space C2 for molding the lens body 7 and a flow path R connecting adjacent cavity spaces C2 in the first direction X are formed.

When the intermediate body 30 is installed to be interposed between the pair of upper and lower molds 51 and 53, a desired cavity space C can be formed at an accurate position relative to the upper surface of the intermediate body 30 by aligning a position of the upper mold 53 with the mother substrate 20 as a reference.

From this state, the cavity space C2 is filled with an uncured molding resin that forms the lens body 7 described above via the flow path R. After the molding resin is heated and cured, the upper mold 53 is released, and a plurality of lens bodies 75 are molded onto the resin molded body 5 to cover each transparent member 6 on the resin molded body 5.

Then, a dicing blade is used to cut the intermediate body 30 into individual light-emitting devices 1A, thereby dividing (singulating) the intermediate body 30 into individual light-emitting devices 1A.

By going through the processes above, a plurality of light-emitting devices 1A can be manufactured at once.

In the manufacturing method for the light-emitting device 1A of the present embodiment, the lens body 7 is molded onto the resin molded body 5 with a transparent member 6 disposed on the resin molded body 5 to close the concave portion 5a formed by recessing a portion of the resin molded body 5 described above. As a result, it is possible to mold the lens body 7 onto the resin molded body 5 with high accuracy while preventing the molding resin that forms the lens body 7 from seeping into the inside of the concave portion 5a.

### Second Embodiment

### Light-Emitting Device

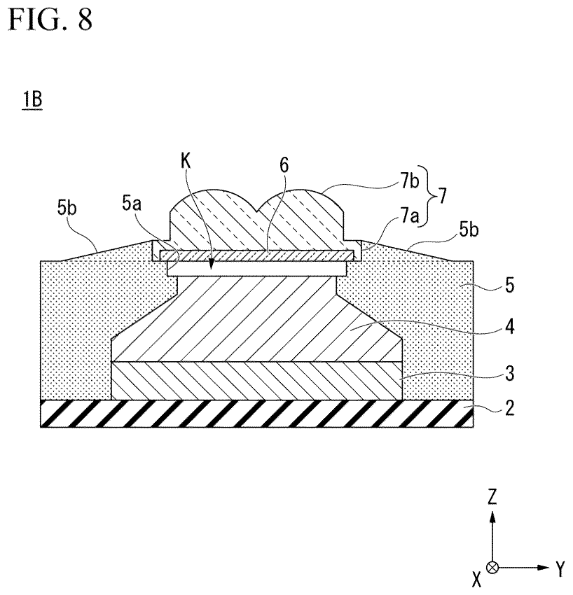

Next, for example, a light-emitting device 1B shown in FIG. 8 will be described as a second embodiment of the present invention.

Note that FIG. 8 is a cross-sectional view which shows a configuration of the light-emitting device 1B. Moreover, in the following description, it is assumed that parts equivalent to the light-emitting device 1A described above will not be described repeatedly and assigned the same reference numerals in the drawings.

As shown in FIG. 8, in addition to a configuration of light-emitting device 1A described above, a light-emitting device 1B of the present embodiment has a configuration in which a resin molded portion 5b covering a periphery of the lens body 7 is provided. The resin molded portion 5b is provided on the resin molded body 5 as a portion of the resin molded body 5 to cover an entire side surface of the base portion 7a of the lens body 7.

When the resin molded portion 5b is formed, after molding the lens body 7 described above, the same uncured molding resin as used for the resin molded body 5 is used to form the resin molded portion by potting to cover the periphery of the base portion 7a of the lens body 7, and then the potted molding resin is heated and cured.

In the light-emitting device 1B of the present embodiment, the resin molded portion 5b covers the periphery of the base portion 7a of the lens body 7, thereby preventing light from leaking to the outside from the side surface of the base portion 7a. In other words, light is generated that returns toward a center of the lens body 7, improving light extraction efficiency.

### Third Embodiment

### Light-Emitting Device

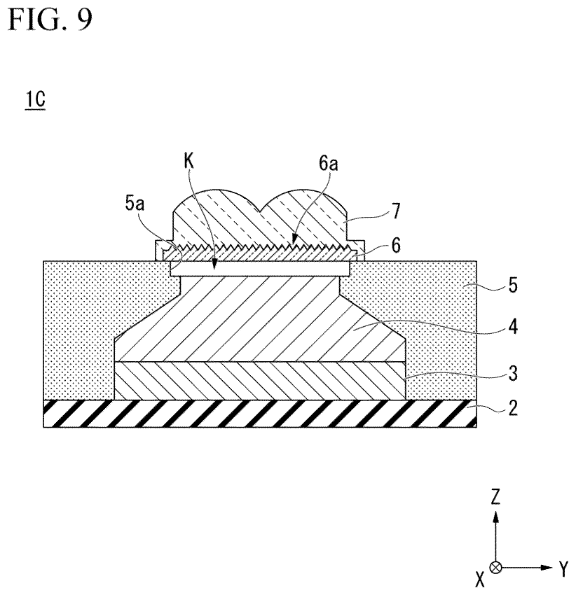

Next, for example, a light-emitting device 1C shown in FIG. 9 will be described as a third embodiment of the present invention.

Note that FIG. 9 is a cross-sectional view which shows a configuration of the light-emitting device 1C. Moreover, in the following description, it is assumed that parts equivalent to the light-emitting device 1A described above will not be described repeatedly and assigned the same reference numerals in the drawings.

As shown in FIG. 9, the light-emitting device 1C of the present embodiment has, in addition to the configuration of the light-emitting device 1A, a light-extraction structure 6a on the upper surface of the transparent member 6. The light-extraction structure 6a has an uneven shape, such as a moth-eye structure or a microlens structure.

In the light-emitting device 1C of the present embodiment, by providing such a light-extraction structure 6a on the upper surface of the transparent member 6, it is possible to increase an extraction efficiency of light emitted from the upper surface of the transparent member 6. This is particularly effective when a refractive index of the transparent member 6 is higher than that of the lens body 7.

### Fourth Embodiment

### Light-Emitting Device

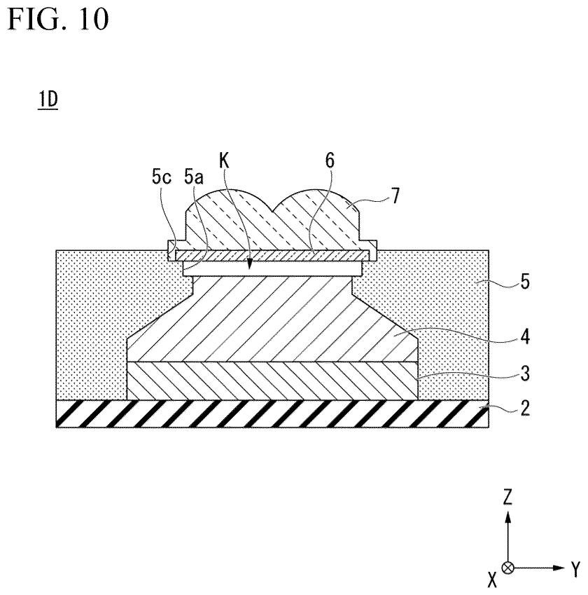

Next, a light-emitting device 1D shown in FIG. 10 will be described as a fourth embodiment of the present invention.

FIG. 10 is a cross-sectional view which shows a configuration of the light-emitting device 1D. Moreover, in the following description, it is assumed that parts equivalent to the light-emitting device 1A described above will not be described repeatedly and assigned the same reference numerals in the drawings.

As shown in FIG. 10, the light-emitting device 1D of the present embodiment has, among the configuration of the light-emitting device 1A described above, a configuration in which the transparent member 6 is fitted into an inside of a stepped portion 5c formed by recessing a periphery of the concave portion 5a of the resin molded body 5. Moreover, by fitting the transparent member 6 into the inside of the stepped portion 5c, the concave portion 5a is closed.

When the stepped portion 5c is formed, a convex portion with a stepped portion is provided in the upper mold 52 described above, and the resin molded body 5 is molded to form the concave portion 5a and the stepped portion 5c.

When the light-emitting device 1D of the present embodiment is manufactured, the lens body 7 is molded onto the resin molded body 5 with the transparent member 6 fitted into the inside of the stepped portion 5c formed by recessing the periphery of the concave portion 5a of the resin molded body 5. As a result, it is possible to mold the lens body 7 onto the resin molded body 5 with high accuracy while preventing the molding resin forming the lens body 7 from seeping into the inside of the concave portion 5a. Note that when the lens body 7 is molded, a portion of the lens body 7 may be formed so that it is positioned on the upper surface of the resin molded body 5.

Furthermore, in the light-emitting device 1D of the present embodiment, the transparent member 6 is fitted into the inside of the stepped portion 5c formed by recessing the periphery of the concave portion 5a of the resin molded body 5, and thereby it is possible to accurately position the transparent member 6 relative to the resin molded body 5 without bonding the transparent member 6 to the resin molded body 5. This also makes it possible to prevent the transparent member 6 from shifting position when the lens body 7 is molded.

### Fifth Embodiment

### Light-Emitting Device

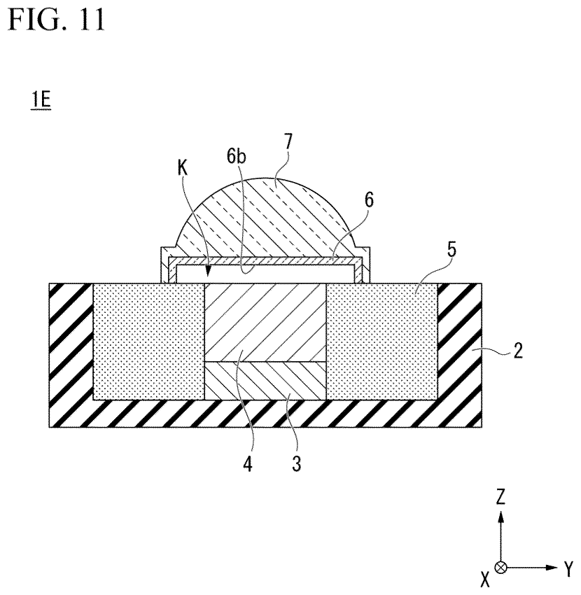

Next, a light-emitting device 1E shown in FIG. 11 will be described as a fifth embodiment of the present invention.

Note that FIG. 11 is a cross-sectional view which shows a configuration of the light-emitting device 1E. Moreover, in the following description, it is assumed that parts equivalent to the light-emitting device 1A described above will not be described repeatedly and assigned the same reference numerals in the drawings.

As shown in FIG. 11, a light-emitting device 1E of the present embodiment has, among the configuration of the light-emitting device 1A, a configuration in which the air layer K is formed by the concave portion 6b formed by recessing a portion of the transparent member 6. That is, in the present embodiment, the transparent member 6 is not flat, but has legs that form the concave portion 6b to form the air layer K. Moreover, the substrate 2, the wavelength conversion member 4, and the lens body 7 are different in shape.

Specifically, the upper surface of the wavelength conversion member 4 is formed on substantially the same surface as the upper surface of the resin molded body 5. The transparent member 6 is provided on the resin molded body 5 to cover the upper surface of the wavelength conversion member 4. As a result, the concave portion 6b provided on the lower surface of the transparent member 6 is closed between the wavelength conversion member 4 and the upper surface of the resin molded body 5.

When the light-emitting device 1E of the present embodiment is manufactured, the lens body 7 is molded onto the resin molded body 5 with the transparent member 6 disposed on the resin molded body 5 to close the concave portion 6b. As a result, it is possible to mold the lens body 7 onto the resin molded body 5 with high accuracy while preventing the molding resin forming the lens body 7 from seeping into an inside of the concave portion 6b.

Therefore, with the light-emitting device 1E of the present embodiment, the high positional accuracy of the lens body 7 described above makes it possible to achieve a desired light distribution and improve light extraction efficiency.

### Sixth Embodiment

### Vehicle Lamp

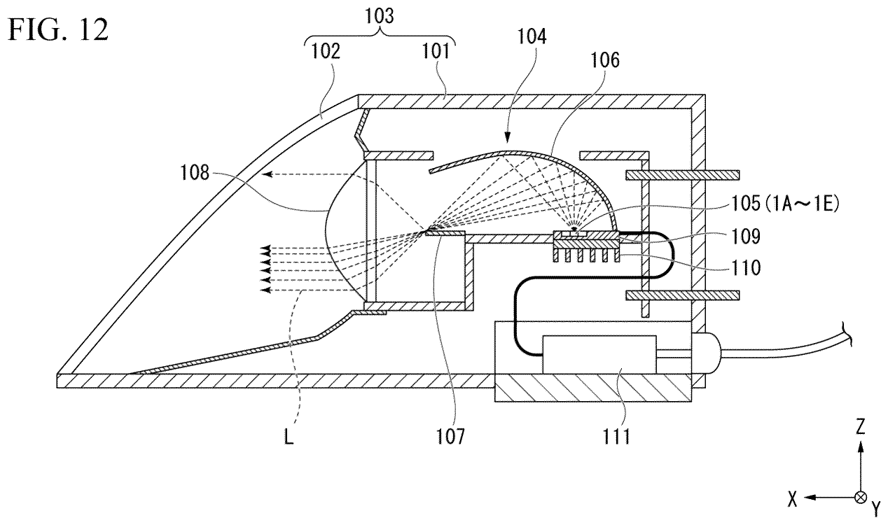

Next, using a sixth embodiment of the present invention, a vehicle lamp 100 shown in FIG. 12 will be described.

Note that FIG. 12 is a cross-sectional view which shows an example of the vehicle lamp 100.

The vehicle lamp 100 of the present embodiment is a vehicle headlamp mounted, for example, on both corners of a front end of a vehicle (not shown).

Specifically, as shown in FIG. 12, this vehicle lamp 100 has a structure in which a light source unit 104 that projects light toward a front of a vehicle (in an +X-axis direction) is disposed inside a lamp body 103 configured from a housing 101 whose front is open and a transparent outer lens 102 that covers an opening of the housing 101.

The light source unit 104 includes, for example, a light source 105 that emits white light (hereinafter simply referred to as light) L, a reflector 106 that reflects the light L emitted upward from the light source 105 toward a front of a vehicle, a shade 107 that blocks (cuts) a portion of the light L reflected by the reflector 106, a projection lens 108 that projects the light L a portion of which has been cut by the shade 107 toward the front of the vehicle, a substrate 109 on one surface side (the upper surface in the present embodiment) of which the light source 105 is mounted, a heat sink 110 that dissipates heat generated by the light source 105 while in contact with the other side (the lower side in the present embodiment) of the substrate 109, and a power supply circuit 111 that drives the light source unit 104.

In the light source unit 104, a low-beam light distribution pattern including a cutoff line at the upper end is formed as a passing beam (low beam) by inverting and projecting a light source image defined by a front end of the shade 107 using the projection lens 108.

Note that the light source unit 104 may also be configured with a cooling fan (not shown) attached to the rear side of the light source unit 104.

In addition, the light source unit 104 may be configured such that a separate light source (not shown) may be disposed below the shade 107, and light emitted by this light source may be projected by the projection lens 108 in a traveling direction of a vehicle as a traveling beam (high beam) to form a high beam light distribution pattern above the low beam light distribution pattern.

In the vehicle lamp 100 of the present embodiment, the light-emitting devices 1A to 1E described above can be suitably used as the light source 105. As a result, it is possible to utilize narrow-angle light L emitted from the light-emitting devices 1A to 1E described above.

Note that the light source unit 104 is not necessarily limited to a projector-type light source unit that projects the light L toward the front of the vehicle using the projection lens 108 described above. For example, it may be a reflector-type light source unit that omits the projection lens and projects the light L toward the front of the vehicle using a reflector including a plurality of reflecting surfaces, or a light-guiding lens-type light source unit that projects the light L toward the front of the vehicle using a light-guiding lens.

While preferred embodiments of the invention have been described and illustrated above, it should be understood that these are exemplary of the invention and are not to be considered as limiting. Additions, omissions, substitutions, and other modifications can be made without departing from the scope of the present invention. Accordingly, the invention is not to be considered as being limited by the foregoing description, and is only limited by the scope of the appended claims.

What is claimed is:

1. A light-emitting device comprising:
a substrate;
a light-emitting element provided on the substrate;
a wavelength conversion member provided on the light-emitting element;
a light-reflecting or light-blocking resin molded body provided on the substrate to cover peripheries of the light-emitting element and the wavelength conversion member;
a transparent member provided on the wavelength conversion member with an air layer interposed between the wavelength conversion member and the transparent member; and
a lens body provided on the resin molded body to cover the transparent member,
wherein the air layer is formed by a concave portion formed by recessing a portion of the resin molded body, and
the transparent member is provided on the resin molded body to close the concave portion.

2. A light-emitting device comprising;
a substrate;
a light-emitting element provided on the substrate;
a wavelength conversion member provided on the light-emitting element;
a light-reflecting or light-blocking resin molded body provided on the substrate to cover peripheries of the light-emitting element and the wavelength conversion member;
a transparent member provided on the wavelength conversion member with an air layer interposed between the wavelength conversion member and the transparent member; and
a lens body provided on the resin molded body to cover the transparent member,
wherein the air layer is formed by a concave portion formed by recessing a portion of the transparent member, and
the transparent member is provided on the resin molded body to close the concave portion.

3. The light-emitting device according to claim 1,
wherein the transparent member is provided to be fitted into an inside of a stepped portion formed by recessing a periphery of the concave portion of the resin molded body.

4. The light-emitting device according to claim 1,
wherein the resin molded body is provided to cover a periphery of the lens body.

5. The light-emitting device according to claim 2,
wherein the resin molded body is provided to cover a periphery of the lens body.

6. A vehicle lamp comprising the light-emitting device according to claim 1.

7. The vehicle lamp comprising the light-emitting device according to claim 2.

8. A manufacturing method of a light-emitting device comprising:
providing a light-emitting element on a substrate;
providing a wavelength conversion member on the light-emitting element;
molding a light-reflecting or light-blocking resin molded body on the substrate to cover peripheries of the light-emitting element and the wavelength conversion member;
providing a transparent member on the wavelength conversion member with an air layer interposed between the wavelength conversion member and the transparent member; and
providing a lens body on the resin molded body to cover the transparent member,
wherein the air layer is formed by a concave portion formed by recessing a portion of the resin molded body, and
the lens body is molded with the transparent member disposed on the resin molded body to close the concave portion.

9. A manufacturing method of a light-emitting device comprising:
providing a light-emitting element on a substrate;
providing a wavelength conversion member on the light-emitting element;
molding a light-reflecting or light-blocking resin molded body on the substrate to cover peripheries of the light-emitting element and the wavelength conversion member;
providing a transparent member on the wavelength conversion member with an air layer interposed between the wavelength conversion member and the transparent member; and
providing a lens body on the resin molded body to cover the transparent member,
wherein the air layer is formed by a concave portion formed by recessing a portion of the transparent member, and
the lens body is molded with the transparent member disposed on the resin molded body to close the concave portion.

10. The manufacturing method of a light-emitting device according to claim 8,
wherein the lens body is molded while the transparent member is fitted into an inside of a stepped portion formed by recessing a periphery of the concave portion of the resin molded body.

11. The manufacturing method of a light-emitting device according to claim 8,
wherein a resin molded body covering a periphery of the lens body is formed by potting after the lens body is molded.

12. The manufacturing method of a light-emitting device according to claim 9,
wherein a resin molded body covering a periphery of the lens body is formed by potting after the lens body is molded.
